(19) United States
(12) Patent Application Publication
(10) Pub. No.: US 2005/0062547 A1
(43) Pub. Date: Mar. 24, 2005

(54) Method and apparatus to generate signals using two or more phase locked loops

(76) Inventor: Yossi Reuven, Hadera (IL)

Correspondence Address: EITAN, PEARL, LATZER & COHEN ZEDEK LLP, 10 ROCKEFELLER PLAZA, SUITE 1001, NEW YORK, NY, 10020, US

(21) Appl. No.: 10/664,850

(22) Filed: Sep. 22, 2003

(51) Int. Cl. H03L 7/00

(52) U.S. Cl. 331/10

(57) ABSTRACT

Briefly, according to embodiments of the invention, there is provided a method and an apparatus that may include a first phase locked loop to set a frequency of an output signal of a first voltage controlled oscillator and a second phase locked loop to receive the output signal of the first voltage controlled oscillator and to lock a second voltage controlled oscillator to the frequency of the output signal provided by the first voltage controlled oscillator.

### BACKGROUND OF THE INVENTION

Transmitters and/or receivers of wireless communication systems such as, for example, a cellular radio communication system, wireless local area network (WLAN) and the like, may include two or more synthesizers that may be used to receive and/or transmit two or more signals, respectively. The two or more signals may have substantially the same frequency. Transmitters and/or receivers having two or more synthesizers may include a circuit to synchronize the output frequencies of the output signals provided by the two or more synthesizers. Each of the two or more synthesizer may be embedded in a single integrated circuit (IC). Thus, at least two ICs and a synchronization unit may be required in order to provide two output signals having substantially the same frequency.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features and advantages thereof, may best be understood by reference to the following detailed description when read with the accompanied drawings in which:

FIG. 1 is a schematic illustration of a wireless communication system according to an exemplary embodiment of the present invention; and

FIG. 2 is a block diagram of a radio device according to some exemplary embodiments of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following detailed description, numerous specific details are set forth in order to provide a thorough understanding of the invention. However it will be understood by those of ordinary skill in the art that the present invention may be practiced without these specific details. In other instances, well-known methods, procedures, components, and circuits have not been described in detail so as not to obscure the present invention.

Some portions of the detailed description, which follow, are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

Unless specifically stated otherwise, as apparent from the following discussions, it is appreciated that throughout the specification discussions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices. In addition, the term “plurality” may be used throughout the specification to describe two or more components, devices, elements, parameters and the like. For example, “plurality of mobile stations” describes two or more mobile stations.

It should be understood that the present invention may be used in a variety of applications. Although the present invention is not limited in this respect, the circuits and techniques disclosed herein may be used in many apparatuses such as transmitters and/or receivers of a radio system. Transmitters and/or receivers intended to be included within the scope of the present invention may be included, by way of example only, within a wireless local area network (WLAN), two-way radio communication system, digital communication system, analog communication system transmitters, cellular radiotelephone communication system, and the like.

Types of cellular radiotelephone communication system intended to be within the scope of the present invention include, although are not limited to, Wideband Code Division Multiple Access (WCDMA), Global System for Mobile communication (GSM), General Packet Radio Service (GPRS), extended GPRS extended data rate for global evolution (EDGE), and the like.

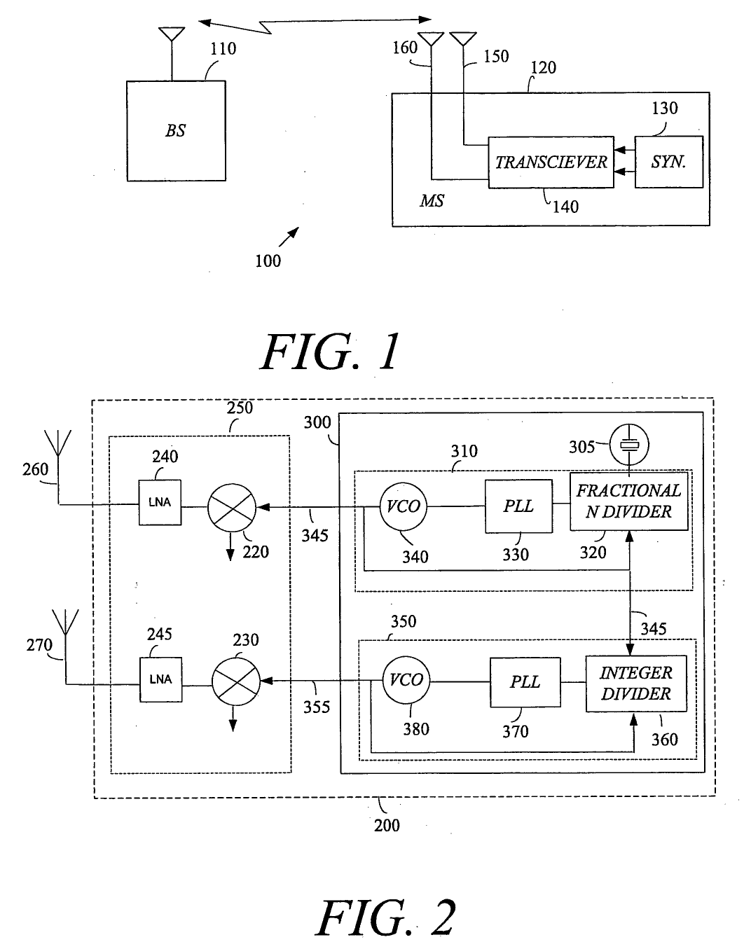

Turning to FIG. 1, a wireless communication system 100 in accordance with exemplary embodiment of the invention is shown. Although the scope of the present invention is not limited in this respect, wireless communication system may include at least one base station (BS) 110 and at least one mobile station 120. In this exemplary embodiment of the invention, MS 120 may include a dual output synthesizer 130, a transceiver 140 and antennas 150 and 160.

Although the scope of the present invention is not limited in this respect, types of antennas that may be used for antenna 150 and/or antenna 160 may include an internal antenna, a dipole antenna, an omni-directional antenna, a monopole antenna, an end fed antenna, a circularly polarized antenna, a micro-strip antenna, a diversity antenna and the like.

Although the scope of the present invention is not limited in this respect, in some embodiments of the invention, dual output synthesizer 130 may include a fractional N synthesizer and a constant division synthesizer. In such embodiments, for example, the fractional N synthesizer may provide a signal with a desired frequency to a first output of dual synthesizer 130. In addition, the fractional N synthesizer may provide at least a portion of the signal to the constant division synthesizer, if desired. The constant division synthesizer may use this signal to provide a second signal to the second output of dual synthesizer 130.

Although the scope of the present invention is not limited to this embodiment, dual synthesizer 130 may provide at least two signals to transceiver 140. For example, transceiver 140 may include at least one GSM receiver and transmitter and synthesizer 140 may provide signals that may be used by transceiver 140 to transmit and receive signals through antennas 150 and 160, if desired. It should be understood by persons skilled in the art that transceiver 140 may include any suitable type of cellular transceiver or WLAN transceiver or two-way radio transceiver or digital radio transceiver and the like.

Turning to FIG. 2, a schematic block diagram of a radio device 200 according to an exemplary embodiment of the invention is shown. Although the scope of the present invention is not limited in this respect, radio device 200 may include a dual output synthesizer 300 and a transceiver 250 to transmit and/or receive signals from antennas 260 and 270. Transceiver 250 may include mixers 220 and 230 and low noise amplifiers (LNA) 240 and 245. In some exemplary embodiments of the present invention, radio device 200 may include a fractional N synthesizer 310 and an integer division synthesizer 350, as described below, both of which synthesizers may be included in dual output synthesizer 300, if desired.

Although the scope of the present invention is not limited in this respect, dual output synthesizer 300 may include an oscillator 305, for example, a crystal oscillator, or any other suitable type of oscillators. Oscillator 305 may be used to provide a fundamental frequency to fractional N synthesizer 310. Fractional N synthesizer 310 may provide an output signal 345 with a desired frequency. Output signal 345 may be provided to integer division synthesizer 350, and the frequency of output signal 345 may be used as a fundamental frequency for integer division synthesizer 350.

In some embodiments of the invention, fractional N synthesizer 310 may include a fractional N divider 320, a phase locked loop (PLL) 330 and a voltage controlled oscillator (VCO) 340. Although the scope of the present invention is not limited in this respect, fractional N synthesizer 310 may be any fractional N synthesizer known to persons skilled in the art. For example, fractional N divider 320 may include other components (not shown) such as, for example, a serial data interface, registers, latches, a reference signal divider to divide the signal of crystal oscillator 305, an accumulator, a digital to analog converter (DAC), dual modulus pre-scalar divider and the like.

Although the scope of the present invention is not limited in this respect, fractional N synthesizer 310 may generate output signal 345 with the desired frequency. In this embodiment, fractional N divider 320 may divide a frequency provided by VCO 340 by N, wherein N may be a rational fraction of integers M and L, i.e., N=M/L, wherein 0<M<L, such that 0<N<1. PLL 330 may set the frequency of output signal 345 by controlling the voltage of VCO 340. PLL 330 may include a phase detector (not shown) to lock the phase of the desired frequency. PLL 330 may vary the voltage of VCO 340 according to the detected phase. Accordingly, VCO 340 may provide output signal 345 at the desired frequency, which may be set by PLL 340.

Although the scope of the present invention is not limited in this respect, the frequency of output signal 355 may be derived from the frequency of output signal 345. In some embodiments of the present invention, at least a portion of output signal 345 may be provided as input to an integer divider 360 of integer synthesizer 350. In some of those embodiments, integer divider 360 may divide the frequency of output signal 345 by one, such that the frequency of output signal 355 of integer synthesizer 350 may be substantially the same as the frequency of output signal 345, which may be the desired frequency. In other embodiments of the invention, integer divider 360 may divide the frequency of output signal 345 by an integer greater than one, for example, 2, 4, 9, 15 and the like, such that the frequency of output signal 355 may be a fraction of the frequency of output signal 345.

Although the scope of the present invention is not limited in this respect, integer division synthesizer 350 may include a PLL 370 and VCO 380. PLL 370 may receive output signal 345 of VCO 340 and may control VCO 380 to provide output signal 355 substantially at the same frequency as that of output signal 345. PLL 370 may include a phase detector (not shown). Integer divider 360 may provide a desired frequency to PLL 370. The phase detector may detect and lock a phase of the desired frequency and PLL 370 may vary a voltage of VCO 380 to provide the desired frequency of output signal 355.

Although the scope of the present invention is not limited in this respect, in an exemplary embodiment of the invention output signals 345 and 355 may be provided as inputs to mixers 220 and 230 of transceiver 250, respectively. In this exemplary embodiment of the invention, signals 345 and 355 may be used to upconvert or downconvert transmitted and/or received signals from antennas 260 and 270, respectively. For example, two signals of the same frequency from different paths may be received simultaneously by antennas 260 and 270, respectively, and the signals may be downconverted to corresponding baseband signals by mixers 220 and 230.

Although the scope of the present invention is not limited in this respect, antenna 260 may receive a signal, which may be amplified by LNA 240 and input to a mixer 220. Mixer 220 may mix output signal 345 to provide downconverted signal 225, if desired. Antenna 270 may receive a signal, which may be amplified by LNA 245 and input to a mixer 230. Mixer 230 may mix output signal 355 to provide downconverted signal 235, if desired. It should be understood by persons skilled in the art that signals 225 and 235 may be downconverted to the baseband frequency and/or baseband signals may be upconverted to the transmission frequency, if desired. In other embodiments of the invention, signals 225 and 235 may be further processed, e.g., to enhance performance parameters of radio device 200, if desired.

Although the scope of the present invention is not limited in this respect, in some embodiments of the invention, PLL 330 and/or VCO 340 and/or PLL 370 and/or VCO 380 may not be included in synthesizers and may be controlled by a controller or processor, if desired.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. An apparatus comprising:
a first phase locked loop to set a frequency of a first output signal of a first voltage controlled oscillator; and
a second phase locked loop to receive the output signal of the first voltage controlled oscillator and to control a second voltage controlled oscillator to provide a second output signal having a frequency derived from the frequency of the first output signal.

2. The apparatus of claim 1, wherein the frequency of the second output signal is a rational fraction of the frequency of the first output signal.

3. The apparatus of claim 1, wherein the frequency of the second output signal is substantially similar to the frequency of the first output signal.

4. The apparatus of claim 2, comprising
a first synthesizer which includes the first phase locked loop and the first voltage controlled oscillator; and
a second synthesizer which includes the second phase locked loop and the second voltage controlled oscillator.

5. The apparatus of claim 4, wherein the first synthesizer comprises a fractional-N synthesizer and the second synthesizer comprises an integer division synthesizer.

6. The apparatus of claim 4, further comprising an oscillator to provide a fundamental frequency to the first synthesizer.

7. The apparatus of claim 6 wherein the oscillator includes a crystal oscillator.

8. A method comprising:
generating by a first synthesizer an output signal having a frequency derived from an input signal having a desired frequency generated by a second synthesizer.

9. The method of claim 8, wherein generating the output signal comprises generating an output signal having a frequency which is a rational fraction of the desired frequency.

10. The method of claim 8 wherein generating comprises:
generating the input signal using a fractional-N synthesizer; and
generating the output signal using an integer division synthesizer.

11. The method of claim 8 comprising:
generating the input signal and the output signal from a signal having a fundamental frequency.

12. An apparatus comprising:
a first phase locked loop to set a frequency of a first output signal of a first voltage controlled oscillator;
a second phase locked loop to receive the output signal of the first voltage controlled oscillator and to control a second voltage controlled oscillator to provide a second output signal having a frequency derived from the frequency the first output signal; and
a transceiver operably coupled to the first and second voltage controlled oscillators and able to transmit and receive signals by at least two dipole antennas.

13. The apparatus of claim 12, wherein the frequency of the second output signal is a rational fraction of the frequency of the first output signal.

14. The apparatus of claim 12, wherein the frequency of the second output signal is substantially similar to the frequency of the first output signal.

15. The apparatus of claim 12, comprising
a first synthesizer which includes the first phase locked loop and the first voltage controlled oscillator; and
a second synthesizer which includes the second phase locked loop and the second voltage controlled oscillator.

16. The apparatus of claim 15, wherein the first synthesizer comprises a fractional-N synthesizer and the second synthesizer comprises an integer division synthesizer.

17. The apparatus of claim 4, further comprising an oscillator to provide a fundamental frequency to the first synthesizer.

18. A wireless communication system comprising:
a mobile station having a dual output synthesizer, which includes:
a first phase locked loop to set a frequency of a first output signal of a first voltage controlled oscillator;
a second phase locked loop to receive the output signal of the first voltage controlled oscillator and to control a second voltage controlled oscillator to provide a second output signal having a frequency derived from the frequency the first output signal; and
a transceiver operably coupled to the first and second voltage controlled oscillators and able to transmit and receive signals by at least two antennas.

19. The wireless communication system of claim 18, wherein the frequency of the second output signal is a rational fraction of the frequency of the first output signal.

20. The wireless communication system of claim 18, wherein the frequency of the second output signal is substantially similar to the frequency of the first output signal.

21. The wireless communication system of claim 18, comprising
a first synthesizer which includes the first phase locked loop and the first voltage controlled oscillator; and
a second synthesizer which includes the second phase locked loop and the second voltage controlled oscillator.

22. The wireless communication system of claim 21, wherein the first synthesizer comprises a fractional-N synthesizer and the second synthesizer comprises an integer division synthesizer.

23. The wireless communication system of claim 18, comprising a base station of a cellular communication system.

24. The wireless communication system of claim 18, wherein at least one antenna of the two or more antennas is an internal antenna.
